(19) United States
(12) Patent Application Publication
(10) Pub. No.: US 2009/0278135 A1
(43) Pub. Date: Nov. 12, 2009

(54) THIN FILM TRANSISTOR, METHOD OF MANUFACTURING THE SAME, AND DISPLAY DEVICE USING THE SAME

(75) Inventor: Yusuke Yoshimura, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/463,812

(22) Filed: May 11, 2009

(30) Foreign Application Priority Data
May 12, 2008 (JP) 2008-124197

(51) Int. Cl. H01L 29/786; H01L 21/336; H01L 33/00

(52) U.S. Cl. 257/72; 257/66; 438/158; 257/E29.294; 257/E21.414; 257/E33.053

(57) ABSTRACT

Disclosed herein is a thin film transistor, including: a gate electrode; a crystallized semiconductor layer formed through a gate insulating film on the gate electrode; and a drain electrode and a source electrode provided on both end sides of the crystallized semiconductor layer, respectively, and provided through impurity doped layers each contacting the crystallized semiconductor layer, respectively.

### BACKGROUND OF THE INVENTION

1. Field of the Invention

The present invention relates to a thin film transistor, a method manufacturing the same, and a display device using the same, and more particularly to a thin film transistor, having a crystallized semiconductor layer used in a channel region, in which non-uniformity of transistor characteristics is reduced, a method manufacturing the same, and a display device using the same.

2. Description of the Related Art

An organic Electro-Luminescence (EL) display device which has recently attracted attention as one of flat panel display devices utilizes a luminous phenomenon when a current is caused to flow through an organic material. Thus, the organic EL display device has a large hidden potential as a display device having a high color reproducibility, a high contrast, a high-speed responsibility, a thin shaped structure, and the like because of its self emission.

Of driving systems for the organic EL display device, an active matrix system having thin film transistors within pixels, respectively, is superior to a passive matrix system in high definition and large screen promotion, and is a technique essential to the organic EL display device.

Here, at least a switching transistor for controlling light and dark of a pixel, and a drive transistor for controlling light emission of an organic EL element need to be provided as the thin film transistors composing the active matrix type organic EL display device. The drive transistor of these transistors needs to have satisfactory ON characteristics because an amount of current caused to flow through the drive transistor is directly reflected in a luminance of a pixel. Also, the drive transistor needs to have a high reliability because a voltage needs to be continuously applied to the drive transistor for an emission time period.

In order to realize the high ON characteristics and the high reliability, the introduction of the manufacture process using crystallized silicon has advanced. A polycrystalline silicon process, using an excimer laser, which is previously introduced into liquid crystal display devices is generally known as a general crystalline silicon process. This technique, for example, is disclosed in Japanese Patent Laid-Open No. Hei 10-242052.

### SUMMARY OF THE INVENTION

However, the excimer laser is a pulsed laser using a gas laser. Thus, the excimer laser radiates a line-like laser beam to amorphous silicon while the line-like laser beam is shifted in a direction vertical to a major axis, thereby melting amorphous silicon. Intensity dispersion of pulses is directly tied with dispersion of crystallization and thus results in dispersion of the characteristics because the excimer laser is the pulsed laser. In the case of the organic EL display device, such a difference in characteristics directly leads to a luminance difference, and is visually recognized as non-uniformity. With regard to this respect, although the dispersion of the characteristics can be suppressed based on a condition of an amount of overlap in a phase of radiation, or the like, it is difficult to find out a basic solution thereto.

On the other hand, there is developed a method of crystallizing amorphous silicon by scanning a continuous oscillated laser beam from a solid-state laser. This method has an advantage that there is no non-uniformity in characteristics caused by the inter-pulse dispersion becoming a problem in the case of the excimer laser because the continuous radiation is obtained. For this reason, the development of this method is being advanced.

However, when the laser beam is radiated to amorphous silicon in the scanning manner as described above, a scanning speed is very slower than a speed of thermal conduction of either silicon or a metal. Therefore, when the laser beam reaches a gate electrode end, the heat is abruptly drawn by a metal of the gate electrode, and thus a sufficient crystalline property can not be obtained in a portion of amorphous silicon located at a short distance from the gate electrode end. On the other hand, in a region of amorphous silicon located at a sufficient difference from the gate electrode end, the heat is sufficiently accumulated in the gate electrode, and the excellent crystalline property is obtained. Even in the case where the region having a poor crystalline property does not lie on a channel region as well as in the case where the region having the poor crystalline property lies on the channel region, the deterioration of the characteristics and the difference in characteristics are caused by the degradation of contact with a source electrode.

The present invention has been made in the light of such circumstances, and it is therefore desirable to provide a thin film transistor, having a crystallized semiconductor layer used in a channel region, in which non-uniformity of transistor characteristics is reduced, a method manufacturing the same, and a display device using the same.

In order to attain the desire described above, according to an embodiment of the present invention, there is provided a thin film transistor including: a gate electrode; a crystallized semiconductor layer formed through a gate insulating film on the gate electrode; and a drain electrode and a source electrode provided on both end sides of the crystallized semiconductor layer, respectively, and provided through impurity doped layers each contacting the crystallized semiconductor layer, respectively; in which when a distance from an end portion contacting the drain electrode in the crystallized semiconductor layer to a position corresponding to an end portion on the drain electrode side of the gate electrode in the crystallized semiconductor layer is defined as a drain side length, a distance from an end portion contacting the source electrode in the crystallized semiconductor layer to a position corresponding to an end portion on the source electrode side of the gate electrode in the crystallized semiconductor layer is defined as a source side length, a length through which the impurity doped layer on the drain electrode side contacts the crystallized semiconductor layer is defined as a drain side contact length, and a length through which the impurity doped layer on the source electrode side contacts the crystallized semiconductor layer is defined as a source side contact length, the source side length is longer than the drain side length, and the source side contact length is longer than the drain side contact length.

In the embodiment of the present invention, the source side length is provided so as to be longer than the drain side length, and the source side contact length is provided so as to be longer than the drain side contact length in the thin film transistor, which results in that it is possible to reduce an influence of the degradation of the crystalline property of the channel region in the source side gate electrode end.

According to another embodiment of the present invention, there is provided a method of manufacturing a thin film transistor, including the steps of: forming a gate electrode on a substrate; forming a gate insulating film so as to cover at least the gate electrode; forming an amorphous semiconductor layer on the gate insulating film, and radiating a laser beam to the amorphous semiconductor layer, thereby forming a crystallized semiconductor layer; and forming a drain electrode and a source electrode on both end sides of the crystallized semiconductor layer through impurity doped layers, respectively; in which when a distance from an end portion contacting the drain electrode in the crystallized semiconductor layer to a position corresponding to an end portion on the drain electrode side of the gate electrode in the crystallized semiconductor layer is defined as a drain side length, a distance from an end portion contacting the source electrode in the crystallized semiconductor layer to a position corresponding to an end portion on the source electrode side of the gate electrode in the crystallized semiconductor layer is defined as a source side length, a length through which the impurity doped layer on the drain electrode side contacts the crystallized semiconductor layer is defined as a drain side contact length, and a length through which the impurity doped layer on the source electrode side contacts the crystallized semiconductor layer is defined as a source side contact length, the source side length is formed so as to be longer than the drain side length, and the source side contact length is formed so as to be longer than the drain side contact length.

In the another embodiment of the present invention, the source side length is formed so as to be longer than the drain side length, and the source side contact length is formed so as to be longer than the drain side contact length in the method of manufacturing a thin film transistor with which the amorphous semiconductor layer is reformed into the crystallized semiconductor layer. As a result, it is possible to reduce an influence of the degradation of the crystalline property of the channel region in the source side gate electrode end.

According to still another embodiment of the present invention, there is provided a display device including: a display area composed of a plurality of pixels; and thin film transistors for driving the plurality of pixels composing the display area; each of the thin film transistors including: a gate electrode; a crystallized semiconductor layer formed through a gate insulating film on the gate electrode; and a drain electrode and a source electrode provided on both end sides of the crystallized semiconductor layer, respectively, and provided through impurity doped layers each contacting the crystallized semiconductor layer, respectively; in which when a distance from an end portion contacting the drain electrode in the crystallized semiconductor layer to a position corresponding to an end portion on the drain electrode side of the gate electrode in the crystallized semiconductor layer is defined as a drain side length, a distance from an end portion contacting the source electrode in the crystallized semiconductor layer to a position corresponding to an end portion on the source electrode side of the gate electrode in the crystallized semiconductor layer is defined as a source side length, a length through which the impurity doped layer on the drain electrode side contacts the crystallized semiconductor layer is defined as a drain side contact length, and a length through which the impurity doped layer on the source electrode side contacts the crystallized semiconductor layer is defined as a source side contact length, the source side length is longer than the drain side length, and the source side contact length is longer than the drain side contact length.

In the still another embodiment of the present invention, the source side length is provided so as to be longer than the drain side length, and the source side contact length is provided so as to be longer than the drain side contact length in each of the thin film transistors for driving the plurality of pixels composing the display device. As a result, it is possible to reduce an influence of the degradation of the crystalline property of the channel region in the source side gate electrode end.

According to the present invention, since the influence of the degradation of the crystalline property in the source side gate electrode end can be reduced in carrying out the crystallization for the channel region, it is possible to suppress the dispersion of the transistor characteristics.

### BRIEF DESCRIPTION OF THE DRAWINGS

FIG. 1 is a schematic cross sectional view showing a thin film transistor according to an embodiment of the present invention;

FIGS. 2A to 2E are respectively schematic cross sectional views explaining respective processes in a method of manufacturing the thin film transistor according to the embodiment of the present invention;

FIG. 3 is a graph explaining a change in transistor characteristics when a source side length (ΔL2) is changed;

FIG. 4 is a graph explaining a change in ON characteristics of the thin film transistor due to changes in drain side contact length and source side contact length;

FIG. 5 is a graph explaining a difference between a change in ON characteristics due to a change in drain side contact length, and a change in ON characteristics due to a change in source side contact length;

FIG. 6 is an equivalent circuit diagram showing a pixel circuit for an organic EL display device;

FIG. 7 is a schematic view showing a flat type module shaped display device as an example of a display device according to an embodiment of the present invention;

FIG. 8 is a perspective view of a television set as an example of application to which the display device according to the embodiment of the present invention is applied;

FIGS. 9A and 9B are respectively a perspective view of a digital camera as another example of application, when viewed from a front side, to which the display device according to the embodiment of the present invention is applied, and a perspective view of the digital camera as the another example of application, when viewed from a back side, to which the display device according to the embodiment of the present invention is applied;

FIG. 10 is a perspective view showing a notebook-size personal computer as still another example of application to which the display device according to the embodiment of the present invention is applied;

FIG. 11 is a perspective view showing a video camera, as yet another example of application, to which the display device according to the embodiment of the present invention is applied;

FIGS. 12A to 12G are respectively a front view of mobile terminal equipment, for example, a mobile phone as a further example of application, in an open state, to which the display device according to the embodiment of the present invention is applied, a side elevational view thereof, a front view thereof in a close state, a left side elevational view thereof, a right side elevational view thereof, a top plan view thereof, and a bottom view thereof;

FIG. 13 is a block diagram showing a configuration of a display image pickup device;

FIG. 14 is a block diagram showing a configuration of an I/O display panel shown in FIG. 13; and

FIG. 15 is a circuit diagram, partly in block, explaining a connection relationship between pixels and an H driver for sensor read.

### DETAILED DESCRIPTION OF THE PREFERRED EMBODIMENTS

The preferred embodiments of the present invention will be described in detail hereinafter with reference to the accompanying drawings.

### Structure of Thin Film Transistor

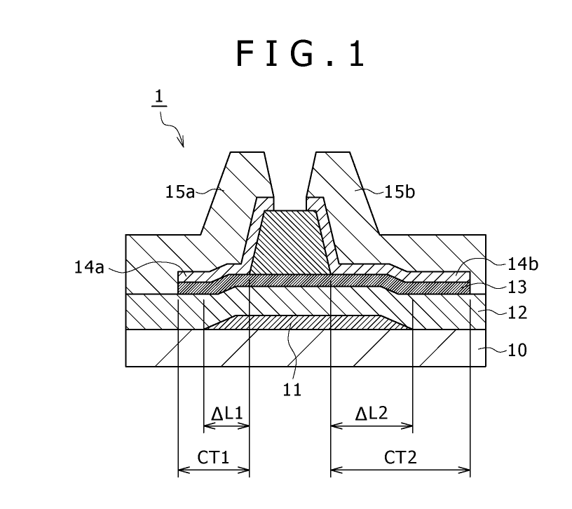

FIG. 1 is a schematic cross sectional view showing a thin film transistor according to an embodiment of the present invention. The feature of the thin film transistor 1 according to the embodiment of the present invention is that when an amorphous semiconductor layer for a channel region is crystallized by utilizing a laser scanning system, a difference between a source contact and a drain contact contributing to characteristics of a transistor is minimized, thereby suppressing a dispersion of the transistor characteristics.

As shown in FIG. 1, the thin film transistor 1 of the embodiment includes a gate electrode 11, a crystallized semiconductor layer 13, and a drain electrode 15a and a source electrode 15b. In this case, the gate electrode 11 is formed on an insulating substrate 10. The crystallized semiconductor layer 13 is formed through a gate insulating film 12 on the gate electrode 11. Also, the drain electrode 15a and the source electrode 15b are provided on both end sides of the crystallized semiconductor layer 13, respectively, and are provided through impurity doped layers 14a and 14b each contacting the crystallized semiconductor layer 13, respectively.

In the thin film transistor 1 of the embodiment, a distance from an end portion contacting the drain electrode 15a in the crystallized semiconductor layer 13 to a position corresponding to an end portion on the drain electrode 15a side of the gate electrode 11 in the crystallized semiconductor layer 13 is set as ΔL1. A distance from an end portion contacting the source electrode 15b in the crystallized semiconductor layer 13 to a position corresponding to an end portion on the source electrode 15b side of the gate electrode 11 in the crystallized semiconductor layer 13 is set as ΔL2. A length through which the impurity doped layer 14a on the drain electrode 15a side contacts the crystallized semiconductor layer 13 is set as a drain side contact length CT1. Also, a length through which the impurity doped layer 14b on the source electrode 15b side contacts the crystallized semiconductor layer 13 is set as a source side contact length CT2. In this case, the source side length ΔL2 is provided so as to be longer than the drain side length ΔL1, and the source side contact length CT2 is provided so as to be longer than the drain side contact length CT1.

Here, the source side length ΔL2 is preferably set as being equal to or longer than 2 μm as will be described later. Also, the source side contact length CT2 is preferably set as being equal to or longer than 5 μm as will be described later.

In the thin film transistor 1 of the embodiment, the source side length ΔL2 is provided so as to be longer than the drain side length ΔL1, and the source side contact length CT2 is provided so as to be longer than the drain side contact length CT1, which results in that it is possible to reduce degradation of a crystalline property of the crystallized semiconductor layer 13 at a source side gate electrode end, that is, an influence of the crystalline property of the crystallized semiconductor layer 13 exerted by radiation of a laser beam. As a result, it is possible to structure the thin film transistor having the stable characteristics.

Specifically, in manufacturing the thin film transistor 1 of the embodiment, the amorphous semiconductor layer is crystallized into the crystallized semiconductor layer 13 by the radiation of the laser beam. During the radiation of the laser beam, when the laser beam reaches the gate electrode end, the heat diffuses from silicon heated by the radiation of the laser beam to the gate electrode 11 through the gate insulating film 12. As a result, a heat quantity which is to be used to crystallize silicon is lost, thereby causing the degradation of the crystalline property.

Moreover, when the radiation of the laser beam progresses, the diffusion of the heat to the gate electrode 11 is prevented because the gate electrode 11 is sufficiently heated, and thus the heat quantity is saturated. As a result, the stable crystalline property is obtained. Due to these phenomena, there is caused a problem that a difference in crystalline property occurs between the gate electrode end and any other portion, and thus the characteristics of the thin film transistors disperse.

Here, only the source side exerts a large influence on the ON characteristics of the thin film transistor. Therefore, the distance ΔL2 from the gate electrode 11 end on the source electrode 15b side in the crystallized semiconductor layer 13 to the end portion contacting the source electrode 15b in the crystallized semiconductor layer 13 is sufficiently ensured. Also, the source side contact length CT2 as the length of the contact between the crystallized semiconductor layer 13 and the impurity doped layer 14b on the source electrode 15b side is sufficiently ensured. Also, the area of the contact between the crystallized semiconductor layer 13 and the impurity doped layer 14b on the source electrode 15b side is sufficiently ensured. Thus, the influence of the gate electrode end having the degraded crystalline property can be reduced without limit. As a result, it is possible to obtain the transistor characteristics having the less dispersion.

It is noted that increasing the length ΔL (the drain side length ΔL1 or the source side length ΔL) results in an increase in parasitic capacitance Cgs between the gate electrode 11 and the source electrode 15b, and an increase in parasitic capacitance Cgd between the gate electrode 11 and the drain electrode 15a. In this case, the increase in parasitic capacitance results in that a drive voltage changes, and this change causes a luminance difference and thus is visually recognized as non-uniformity. As will be described later, however, since dependency of the ON characteristics on the drain side length ΔL1 in the thin film transistor 1 is not found out, the parasitic capacitance is reduced by setting a size of the drain side length ΔL1 at about 1 μm which can be produced in terms of a manufacture process. In addition, the portion becoming a problem in terms of the parasitic capacitance is connected to the drain portion, thereby making it possible to improve the dispersion of the characteristics while the problem about the parasitic capacitance is suppressed.

### Method of Manufacturing Thin Film Transistor

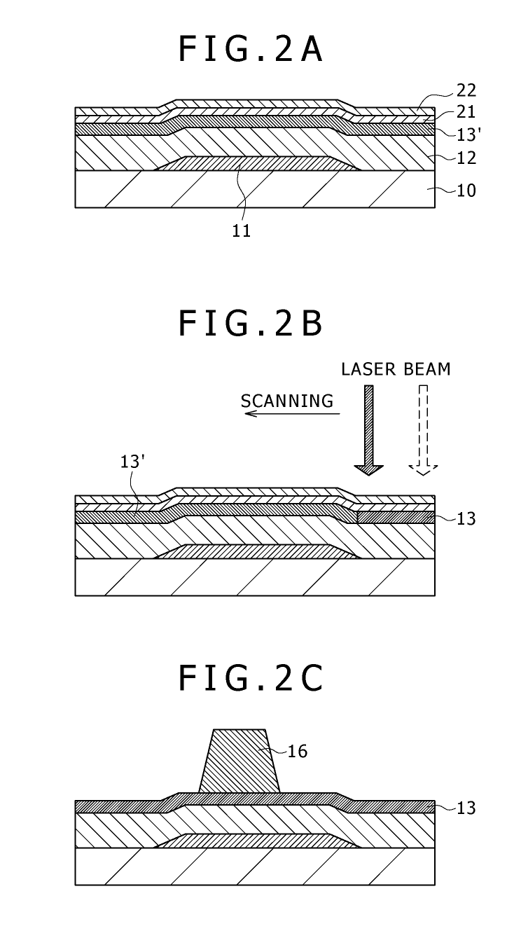

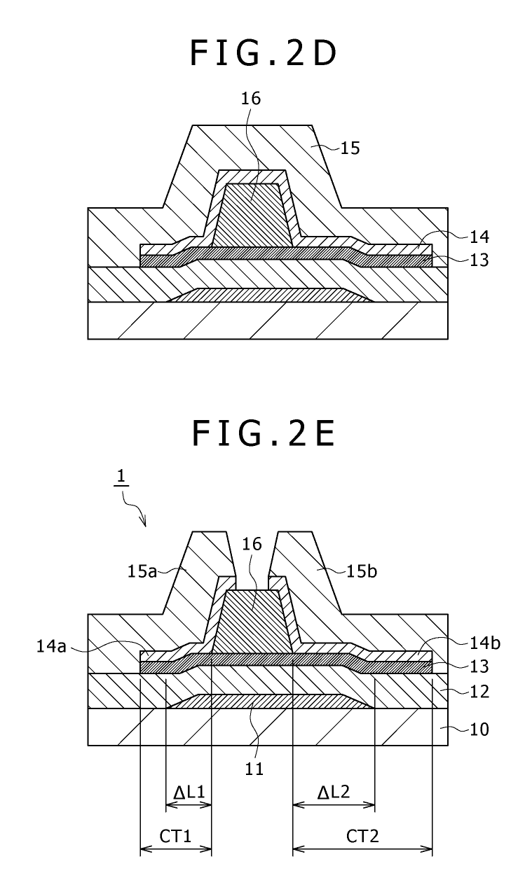

FIGS. 2A to 2E are respectively schematic cross sectional views explaining respective processes in a method of manufacturing the thin film transistor according to the embodiment of the present invention. Firstly, as shown in FIG. 2A, a molybdenum film is deposited on a surface of the insulating substrate 10 by utilizing a sputtering method or the like, and, for example, a photolithography process and a suitable etching method are used for the molybdenum film, thereby forming the gate electrode 11.

Subsequently, the gate insulating film 12 made of a laminated film composed of a silicon nitride and a silicon oxide is formed by, for example, utilizing a plasma Chemical Vapor Deposition (CVD) method. Moreover, an amorphous silicon layer 13′, and a silicon oxide film 21 as a buffer layer for preventing metal diffusion into the amorphous silicon layer 13′ are continuously deposited on the gate insulating film 12. Next, a molybdenum film 22 as a metallic layer (heat converting layer) for absorbing an energy of a laser beam, and converting the energy of the laser beam into heat is deposited on the silicon oxide film 21 by utilizing the sputtering method.

Next, as shown in FIG. 2B, a continuous laser beam is radiated from, for example, the source region side in the thin film transistor to be finally obtained in a scanning manner by using a solid-state laser or the like, thereby crystallizing the amorphous silicon layer 13′. The crystallized semiconductor layer 13 is formed in the crystallization process.

After completion of the crystallization of the amorphous silicon layer 13′, the unnecessary molybdenum film 22 and silicon oxide film 21 are successively etched away. Next, as shown in FIG. 2C, a silicon nitride film serving as an etching stopper 16 is formed on the crystallized semiconductor layer 13 by, for example, utilizing the plasma CVD method.

The etching stopper 16 is formed so that as previously stated, the source side length ΔL2 and the drain side length ΔL1 shows a relationship of ΔL2>ΔL1. In the crystallized semiconductor layer 13, the channel region is formed just under the etching stopper 16, and the source region and the drain region are formed on the both sides of the channel region, respectively.

Subsequently, as shown in FIG. 2D, an impurity doped layer 14 made from an n+-type amorphous silicon film is formed so as to cover the etching stopper 16, and an exposed portion in the periphery of the crystallized semiconductor layer 13. Moreover, a metallic layer 15 is formed so as to cover the impurity doped layer 14.

After that, when the metallic layer 15 and the impurity doped layer 14 overlying the etching stopper 16 are selectively etched away, as shown in FIG. 2E, the laminated layer composed of the impurity doped layer 14 and the metallic layer 15 is partitioned into two parts. That is to say, there are formed the impurity doped layer 14a and the drain electrode 15a on the drain side, and the impurity doped layer 14b and the source electrode 15b on the source side. After that, a silicon nitride film (not shown) or the like serving as a passivation film is formed over the entire surface thereof, thereby completing the inversely-staggered thin film transistor.

By implementing the manufacturing method as described above, it is possible to obtain the thin film transistor 1 in which the source side length ΔL2 is provided so as to be longer than the drain side length ΔL1, and the source side contact length CT2 is provided so as to be longer than the drain side contact length CT1.

### Characteristics of Thin Film Transistor

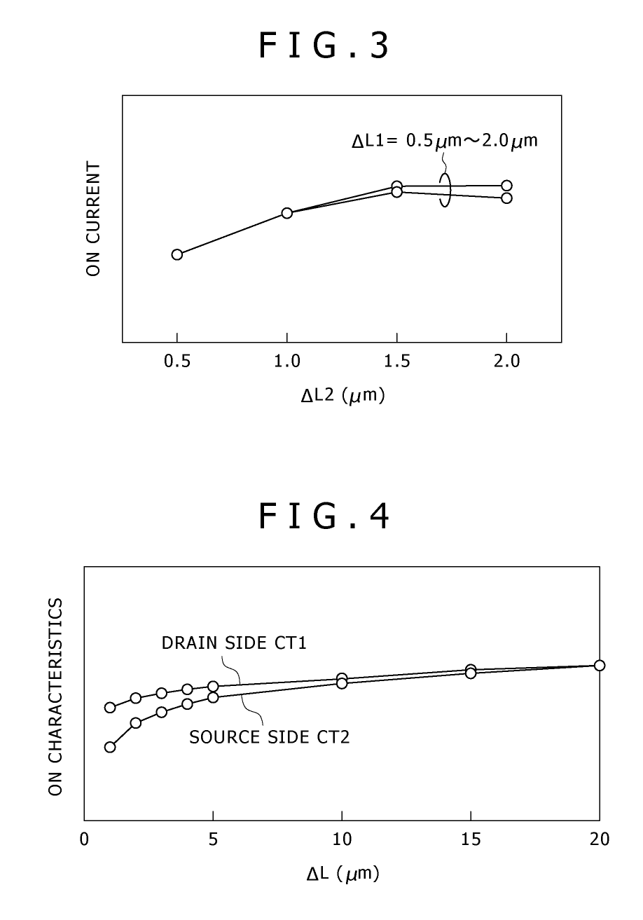

FIG. 3 is a graph explaining a change in transistor characteristics when the source side length ΔL2 is changed. In FIG. 3, an axis of abscissas represents the source side length ΔL2, and an axis of ordinate represents ON characteristics as one of the characteristics of the thin film transistor 1. In this case, the drain side length ΔL1 is used as a parameter in the graph.

As apparent from FIG. 3, the dependency of the ON characteristics on the drain side length ΔL1 in the thin film transistor 1 is not found out. On the other hand, the improvement in the ON characteristics is found out when the source side length ΔL2 is increased. In particular, when the source side length ΔL2 of 2 μm or more is ensured, the ON characteristics have a tendency to be saturated. Thus, it can be said that this tendency is enough to suppress the dispersion of the transistor characteristics.

FIG. 4 is a graph explaining a change in ON characteristics of the thin film transistor 1 due to changes in drain side contact length CT1 and source side contact length CT2. One characteristic curve in the graph corresponds to a change in drain side contact length CT1, and the other in the graph corresponds to a change in source side contact length CT2. It is noted that with regard to the characteristic curves of the drain side contact length CT1 and the source side contact length CT2, the measurement was carried out under the condition that the contact length on the other side was set at 3 μm. Although the improvement in the ON characteristics is found out even in the case of the contact length on any side so long as it is made longer, the improvement in the ON characteristics is more remarkably shown in the change in source side contact length CT2 than in drain side contact length CT1.

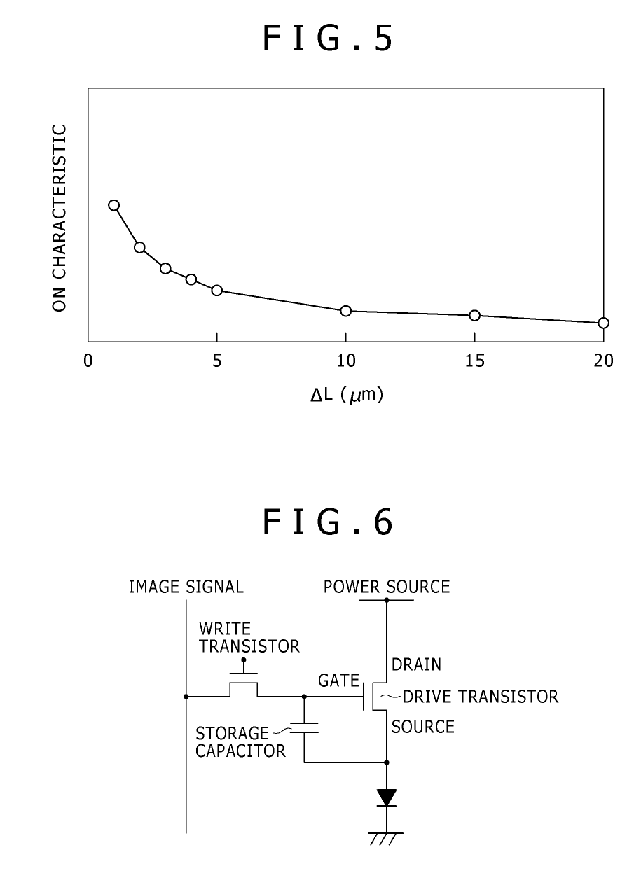

FIG. 5 is a graph showing a difference ΔL between a change in ON characteristics due to a change in drain side contact length CT1, and a change in ON characteristics due to a change in source side contact length CT2. As apparent from FIGS. 4 and 5, when the contact length becomes long, the dispersion of the characteristics caused by the degradation of the crystalline property is suppressed, and it can be said that setting the difference ΔL at 5 μm or more is enough.

FIG. 6 is an equivalent circuit diagram showing a pixel circuit for an organic EL display device. A suitable voltage is supplied from a power source to a drain terminal of a drive transistor, and a suitable voltage is supplied from a source terminal side of the drive transistor to an organic EL element. Also, a signal is supplied from a write transistor to a gate terminal of the drive transistor. An image signal is supplied to the write transistor, and is written from the write transistor to a storage capacitor by controlling the gate of the write transistor in accordance with a scanning signal, thereby controlling the gate of the drive transistor. As a result, the drive transistor supplies the voltage corresponding to the image signal to the organic EL element.

The thin film transistor of the embodiment is applied to the drive transistor in the pixel circuit as shown in FIG. 6. Specifically, the thin film transistor is designed in such a way that the length, ΔL2, on the source side connected to each of an anode electrode of the organic EL element, and one electrode of the storage capacitor is set as being equal to or larger than 2 μm (ΔL2≧2 μm), and the source side contact length CT2 is set as being equal to or larger than 5 μm (CT2≧5 μm) while the drain side length ΔL1=1 μm, and the drain side contact length CT1=3 μm are maintained. As a result, the satisfactory transistor characteristics can be obtained without depending on the scanning direction of the laser beam, and the arrangement of the pixels.

### Effects of the Embodiment

In the thin film transistor manufactured based on the process for crystallizing the amorphous semiconductor layer in the scanning manner using the laser, the source side length ΔL2 is set as being longer than the drain side length ΔL1, and the source side contact length CT2 is set as being longer than the drain side contact length CT1. As a result, the influence of the degradation of the crystalline property in the gate electrode end is reduced, thereby making it possible to obtain the transistor characteristics having the less dispersion. Therefore, for example, a capacitor concerned with a threshold changing circuit within the pixel circuit in the organic EL display device is disposed on the drain side, whereby a display panel having a high quality can be realized without depending on the scanning direction of the laser beam, and the arrangement of the pixels while a bad influence exerted on the display characteristics of the organic EL display device by the parasitic capacitance is excluded.

### Display Device

Next, a description will be given with respect to a display device according to an embodiment of the present invention.

The display device according to this embodiment of the present invention includes a display area composed of a plurality of pixels, and thin film transistors for driving the plurality of pixels composing the display area. In this case, each of the thin film transistors is structured as the thin film transistor described in the embodiment previously described with reference to FIG. 1.

That is to say, each of the thin film transistors includes the gate electrode, the crystallized semiconductor layer formed through the gate insulating film on the gate electrode, and the drain electrode and the source electrode provided on the both end sides of the crystallized semiconductor layer, respectively, and provided through the impurity doped layers each contacting the crystallized semiconductor layer, respectively.

In addition, the distance from the end portion contacting the drain electrode in the crystallized semiconductor layer to the position corresponding to the end portion on the drain electrode side of the gate electrode in the crystallized semiconductor layer is set as ΔL1. The distance from the end portion contacting the source electrode in the crystallized semiconductor layer to the position corresponding to the end portion on the source electrode side of the gate electrode in the crystallized semiconductor layer is set as ΔL2. The length through which the impurity doped layer on the drain electrode side contacts the crystallized semiconductor layer is set as the drain side contact length CT1. Also, the length through which the impurity doped layer on the source electrode side contacts the crystallized semiconductor layer is set as the source side contact length CT2. In this case, the source side length ΔL2 is provided so as to be longer than the drain side length ΔL1, and the source side contact length CT2 is provided so as to be longer than the drain side contact length CT1.

Here, the source side length ΔL2 is preferably set as being equal to or longer than 2 μm. Also, the source side contact length CT2 is preferably set as being equal to or longer than 5 μm.

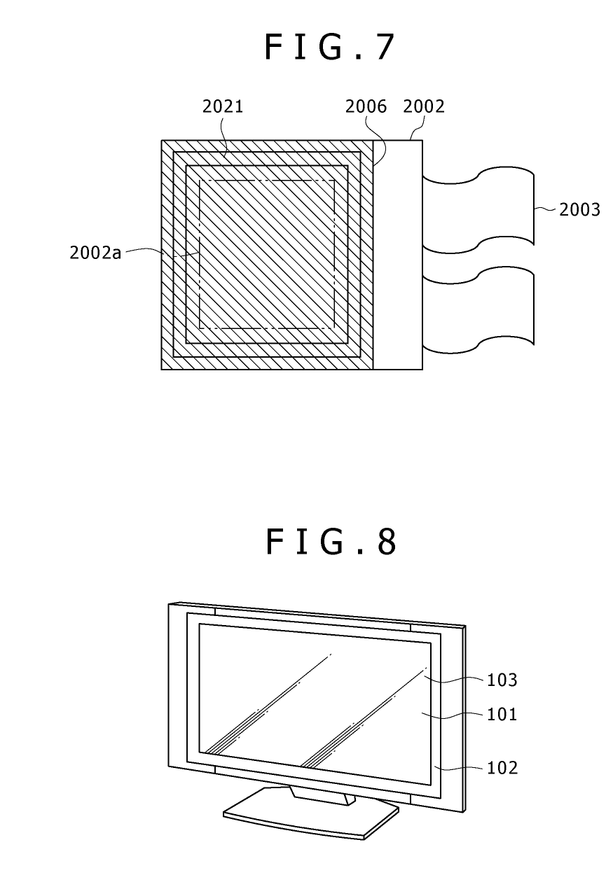

The display device according to this embodiment of the present invention includes a flat type module shaped display device as shown in FIG. 7. For example, the display module is obtained as follows. That is to say, a pixel array portion 2002a is provided in which pixels each composed of a display area, the thin film transistor of the embodiment previously described with reference to FIG. 1, and the like are formed in a matrix integrally with one another on an insulating substrate 2002. An adhesive agent 2021 is disposed so as to surround the pixel array portion (pixel matrix portion) 2002a. Also, a counter substrate 2006 made of a glass or the like is stuck to the insulating substrate 2002, thereby obtaining the display module. The transparent counter substrate 2006 may be provided with a color filter, a protective film, a light shielding film, and the like as may be necessary. The display module may be provide with a Flexible Printed Circuit board (FPC) 2023 serving as a connector through which a signal or the like is inputted/outputted to/from the pixel array portion 2002a from/to the outside.

The display device of this embodiment of the present invention includes a projection type display device for enlarging and projecting a displayed image, and the like in addition to a liquid crystal display device using a liquid crystal in a display area, and an organic EL display device using organic EL elements in a display area.

### Examples of Application to Electronic Apparatuses

The display device according to the embodiment of the present invention described above can be applied to display devices, of electronic apparatuses in all the fields, in each of which a video signal inputted to the electronic apparatus, or a video signal generated in the electronic apparatus is displayed in the form of either an image or a video image. These electronic apparatuses are typified by various electronic apparatuses, shown in FIG. 8 to FIGS. 12A to 12G, such as a television set, a projection apparatus, a digital camera, a notebook-size personal computer, mobile terminal equipment such as a mobile phone, and a video camera. Hereinafter, examples of electronic apparatuses to each of which the display device according to the embodiment of the present invention is applied will be described.

FIG. 8 is a perspective view showing a television set, as an example of application, to which the display device according to the embodiment of the present invention is applied. The television set according to the example of application includes an image display screen portion 101 composed of a front panel 102, a filter glass 103, and the like. Also, the television set is manufactured by using the display device according to the embodiment of the present invention as the image display screen portion 101.

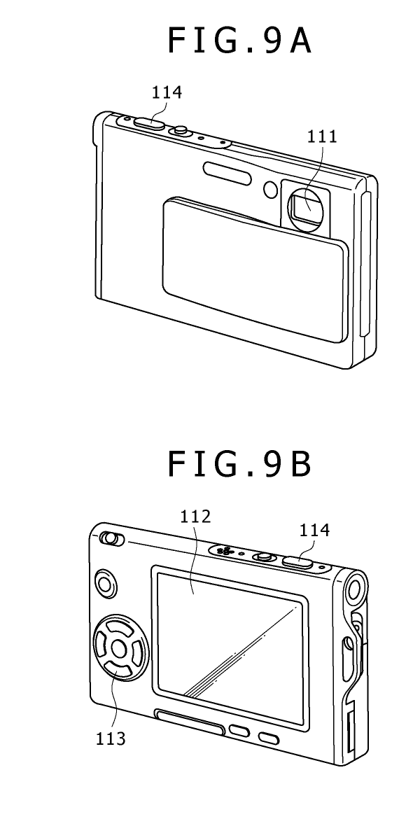

FIGS. 9A and 9B are respectively perspective views each showing a digital camera, as another example of application, to which the display device according to the embodiment of the present invention is applied. FIG. 9A is a perspective view when the digital camera is viewed from a front side, and FIG. 9B is a perspective view when the digital camera is viewed from a back side. The digital camera according to the another example of application includes a light emitting portion 111 for flash, a display portion 112, a menu switch 113, a shutter button 114, and the like. The digital camera is manufactured by using the display device according to the embodiment of the present invention as the display portion 112.

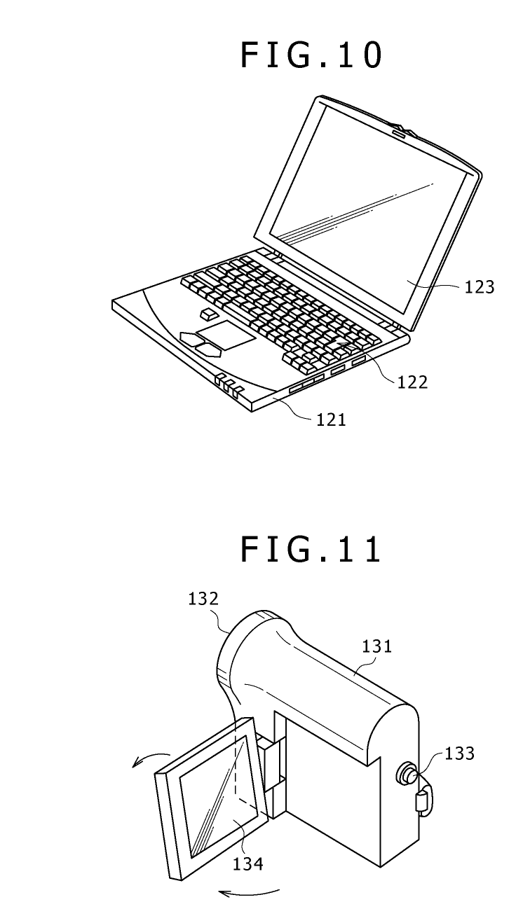

FIG. 10 is a perspective view showing a notebook-size personal computer, as still another example of application, to which the display device according to the embodiment of the present invention is applied. The notebook-size personal computer according to the still another example of application includes a main body 121, a keyboard 122 which is manipulated when characters or the like are inputted, a display portion 123 for displaying thereon an image, and the like. The notebook-size personal computer is manufactured by using the display device according to the embodiment of the present invention as the display portion 123.

FIG. 11 is a perspective view showing a video camera, as yet another example of application, to which the display device according to the embodiment of the present invention is applied. The video camera according to the yet another example of application includes a main body portion 131, a lens 132 which captures an image of a subject and which is provided on a side surface directed forward, a start/stop switch 133 which is manipulated when an image of a subject is captured, a display portion 134, and the like. The video camera is manufactured by using the display device according to the embodiment of the present invention as the display portion 134.

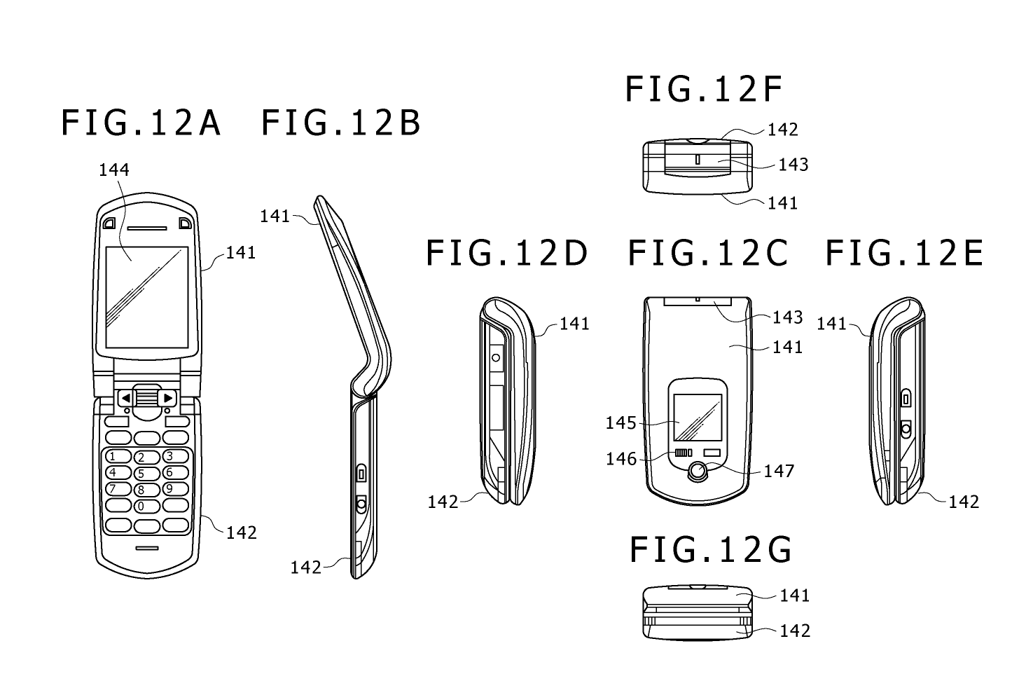

FIGS. 12A to 12G are respectively views showing mobile terminal equipment, for example, a mobile phone, as a further example of application, to which the display device according to the embodiment of the present invention is applied. FIG. 12A is a front view in an open state of the mobile phone, FIG. 12B is a side elevational view in the open state of the mobile phone, FIG. 12C is a front view in a close state of the mobile phone, FIG. 12D is a left side elevational view of the mobile phone, FIG. 12E is a right side elevational view of the mobile phone, FIG. 12F is a top plan view of the mobile phone, and FIG. 12G is a bottom view of the mobile phone. The mobile phone according to the further example of application includes an upper chassis 141, a lower chassis 142, a connection portion (a hinge portion in this case) 143, a display portion 144, a sub-display portion 145, a picture light 146, a camera 147, and the like. The mobile phone is manufactured by using the display device according to the embodiment of the present invention as either the display portion 144 or the sub-display portion 145.

### Display Image Pickup Device

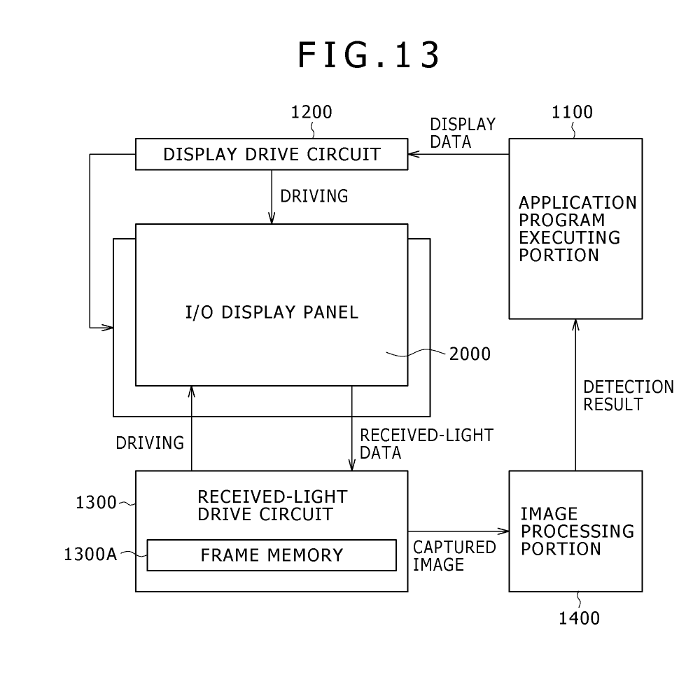

The display device according to the embodiment of the present invention can be applied to a display image pickup device which will be described below. In addition, the display image pickup device can be applied to each of the various kinds of electronic apparatuses previously described. FIG. 13 shows an entire configuration of the display image pickup device. The display image pickup device includes an I/O display panel 2000, a backlight 1500, a display drive circuit 1200, a received-light drive circuit 1300, an image processing portion 1400, and an application program executing portion 1100.

The I/O display panel 2000 is composed of a liquid crystal display panel in which a plurality of pixels are disposed in a matrix over an entire surface. The I/O display panel 2000 has a display function and an image pickup function. With the display function, an image such as a predetermined figure or characters based on display data is displayed while a line-sequential operation is carried out. Also, with the image pickup function, an image of an object which either contacts or approaches the I/O display panel 2000 as will be described later is captured. In addition, the backlight 1500 is a light source for the I/O display panel 2000 in which, for example, a plurality of light emitting diodes are disposed. The backlight 1500 carries out an ON/OFF operation at a high speed at a predetermined timing synchronous with an operation timing of the I/O display panel 2000.

The display drive circuit 1200 is a circuit for driving the I/O display panel 2000 (for driving the I/O display panel 2000 in the line-sequential manner) so that an image based on the display data is displayed on the I/O display panel 2000 (so that the display operation is carried out).

The received-light drive circuit 1300 is a circuit for driving the I/O display panel 2000 (for driving the I/O display panel 2000 in the line-sequential manner) so that data on the received lights is obtained in the I/O display panel 2000 (so that an image of an object is captured). It is noted that the data on the received lights in the respective pixels, for example, is accumulated in a frame memory 1300A in frames, and is then outputted to the image processing portion 1400 so as to obtain the captured image.

The image processing portion 1400 executes predetermined image processing (arithmetic operating processing) based on the captured image the data on which is outputted from the received-light drive circuit 1300, thereby detecting and acquiring information on the object (such as position coordinate data, and data on a shape and a size of the object) which either contacts or approaches the I/O display panel 2000. It is noted that details of the detection processing will be described later.

The application program executing portion 1100 executes processing corresponding to predetermined application software based on the detection results obtained from the image processing portion 1400. For example, processing for containing the position coordinates of the detected object in the display data, and displaying the display data on the I/O display panel 2000, and the like are given as the processing described above. It is noted that the display data generated from the application program executing portion 1100 is supplied to the display drive circuit 1200.

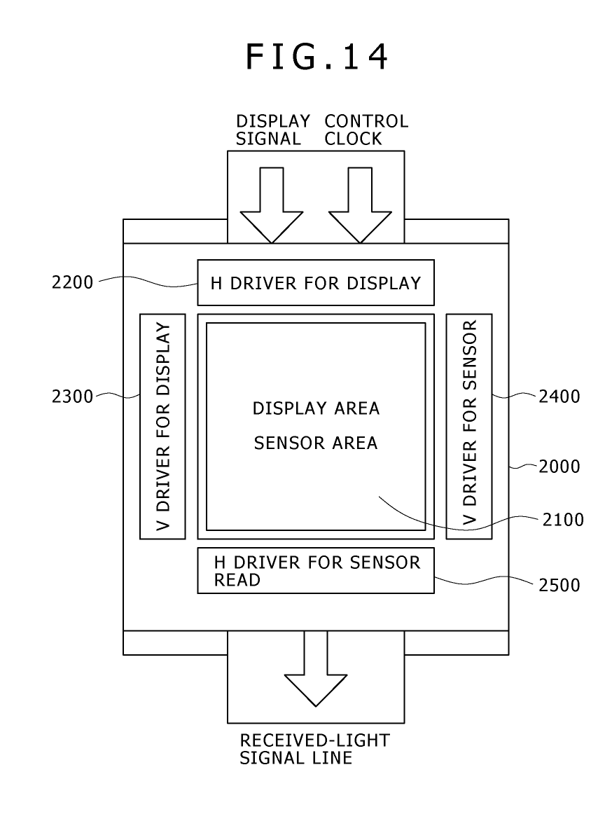

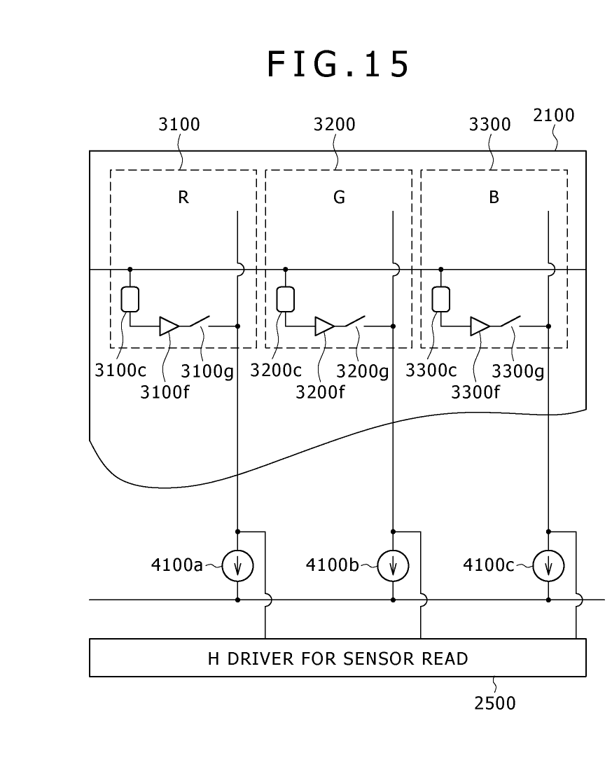

Next, a detailed configuration of the I/O display panel 2000 will be described with reference to FIG. 14. The I/O display panel 2000 includes a display area (sensor area) 2100, and an H driver 2200 for display, a V driver 2300 for display, an H driver 2500 for sensor read, and a V driver 2400 for a sensor.

The display area (sensor area) 2100 is an area through which lights from organic electro-luminescence elements are modulated to radiate display lights, and an image of an object either contacting or approaching this area is captured. Also, the organic electro-luminescence elements as light emitting elements (display elements), and light receiving elements (image pickup elements) which will be described later are each disposed in matrices, respectively.

The H driver 2200 for display drives the organic electro-luminescence elements of the pixels within the display area 2100 together with the V driver 2300 for display in accordance with a display signal for display drive, and a control clock which are supplied from the display drive circuit 1200.

The H driver 2500 for sensor read drives the light receiving elements of the pixels within the sensor area 2100 in the line-sequential manner together with the V driver 2400 for a sensor, thereby acquiring the received-light signal.

Next, a description will be given with respect to a connection relationship between the pixels within the display area 2100, and the H driver 2500 for sensor read. A pixel 3100 for Red (R), a pixel 3200 for Green (G), and a pixel 3300 for Blue (B) are displayed side by side in the display area 2100.

The electric charges accumulated in capacitors connected to light receiving sensors 3100c, 3200c, and 3300c in the pixels 3100, 3200 and 3300 are amplified in buffer amplifiers 3100f, 3200f and 3300f, respectively, and are then supplied to the H driver 2500 for sensor read through electrodes for signal output at a timing at which each of read switches 3100g, 3200g and 3300g is turned ON. It is noted that constant current sources 4100a, 4100b and 4100c are connected to the electrodes for signal output, respectively, so that the signal corresponding to a quantity of received light is detected at high sensitivity by the H driver 2500 for sensor read.

The present application contains subject matter related to that disclosed in Japanese Priority Patent Application JP 2008-124197 filed in the Japan Patent Office on May 12, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thin film transistor, comprising:
a gate electrode;
a crystallized semiconductor layer formed through a gate insulating film on said gate electrode; and
a drain electrode and a source electrode provided on both end sides of said crystallized semiconductor layer, respectively, and provided through impurity doped layers each contacting said crystallized semiconductor layer, respectively,
wherein when a distance from an end portion contacting said drain electrode in said crystallized semiconductor layer to a position corresponding to an end portion on the drain electrode side of said gate electrode in said crystallized semiconductor layer is defined as a drain side length, a distance from an end portion contacting said source electrode in said crystallized semiconductor layer to a position corresponding to an end portion on the source electrode side of said gate electrode in said crystallized semiconductor layer is defined as a source side length, a length through which said impurity doped layer on the drain electrode side contacts said crystallized semiconductor layer is defined as a drain side contact length, and a length through which said impurity doped layer on the source electrode side contacts said crystallized semiconductor layer is defined as a source side contact length, the source side length is longer than the drain side length, and the source side contact length is longer than the drain side contact length.

2. The thin film transistor according to claim 1, wherein the source side length is provided so as to be 2 μm or more.

3. The thin film transistor according to claim 1, wherein the source side contact length is provided so as to be 5 μm or more.

4. A method of manufacturing a thin film transistor, comprising the steps of:
forming a gate electrode on a substrate;
forming a gate insulating film so as to cover at least said gate electrode;
forming an amorphous semiconductor layer on said gate insulating film, and radiating a laser beam to said amorphous semiconductor layer, thereby forming a crystallized semiconductor layer; and
forming a drain electrode and a source electrode on both end sides of said crystallized semiconductor layer through impurity doped layers, respectively,
wherein when a distance from an end portion contacting said drain electrode in said crystallized semiconductor layer to a position corresponding to an end portion on the drain electrode side of said gate electrode in said crystallized semiconductor layer is defined as a drain side length, a distance from an end portion contacting said source electrode in said crystallized semiconductor layer to a position corresponding to an end portion on the source electrode side of said gate electrode in said crystallized semiconductor layer is defined as a source side length, a length through which said impurity doped layer on the drain electrode side contacts said crystallized semiconductor layer is defined as a drain side contact length, and a length through which said impurity doped layer on the source electrode side contacts said crystallized semiconductor layer is defined as a source side contact length, the source side length is formed so as to be longer than the drain side length, and the source side contact length is formed so as to be longer than the drain side contact length.

5. The method of manufacturing the thin film transistor according to claim 4, wherein a continuous laser beam is radiated to said amorphous semiconductor layer, thereby forming said crystallized semiconductor layer.

6. A display device, comprising:
a display area composed of a plurality of pixels; and
thin film transistors configured to drive said plurality of pixels composing said display area;
each of said thin film transistors including
a gate electrode,
a crystallized semiconductor layer formed through a gate insulating film on said gate electrode, and
a drain electrode and a source electrode provided on both end sides of said crystallized semiconductor layer, respectively, and provided through impurity doped layers each contacting said crystallized semiconductor layer, respectively,
wherein when a distance from an end portion contacting said drain electrode in said crystallized semiconductor layer to a position corresponding to an end portion on the drain electrode side of said gate electrode in said crystallized semiconductor layer is defined as a drain side length, a distance from an end portion contacting said source electrode in said crystallized semiconductor layer to a position corresponding to an end portion on the source electrode side of said gate electrode in said crystallized semiconductor layer is defined as a source side length, a length through which said impurity doped layer on the drain electrode side contacts said crystallized semiconductor layer is defined as a drain side contact length, and a length through which said impurity doped layer on the source electrode side contacts said crystallized semiconductor layer is defined as a source side contact length, the source side length is longer than the drain side length, and the source side contact length is longer than the drain side contact length.

7. The display device according to claim 6, wherein the source side length is provided so as to be 2 μm or more.

8. The display device according to claim 6, wherein the source side contact length is provided so as to be 5 μm or more.
